(19) United States
(12) Patent Application Publication
(10) Pub. No.: US 2025/0194310 A1
(43) Pub. Date: Jun. 12, 2025

(54) DISPLAY DEVICE

(71) Applicant: INNOLUX CORPORATION, Miao-Li County (TW)

(72) Inventors: Wen-Tse LI, Miao-Li County (TW); Shih-Fu LIAO, Miao-Li County (TW); I-An YAO, Miao-Li County (TW)

(21) Appl. No.: 18/941,275

(22) Filed: Nov. 8, 2024

(30) Foreign Application Priority Data
Dec. 8, 2023 (CN) 202311686396.5

(51) Int. Cl. H01L 33/58; H01L 25/075

(52) U.S. Cl. CPC H10H 20/855; H01L 25/0753

(57) ABSTRACT

A display device includes a first substrate, a second substrate, an adhesive layer, at least one light-emitting unit, and an intermediate layer. The second substrate is disposed opposite to the first substrate. The adhesive layer is disposed between the first substrate and the second substrate. The light-emitting unit is disposed between the adhesive layer and the first substrate, and the light-emitting unit includes at least one light-emitting element. The surface of the light-emitting element facing toward the adhesive layer is configured with a plurality of micro structures. The intermediate layer is disposed between the adhesive layer and the micro structures. The refractive index of the intermediate layer is greater than 1 and less than the refractive index of the adhesive layer.

### CROSS REFERENCE TO RELATED APPLICATIONS

This Non-provisional application claims priority under 35 U.S.C. § 119 (a) on Patent Application No(s). 202311686396.5 filed in China on Dec. 8, 2023, the entire contents of which are hereby incorporated by reference.

### BACKGROUND

### Technology Field

The disclosure relates to a display device and, in particular, to a display device with light-emitting diodes (LEDs).

### Description of Related Art

With the development of digital technology, display devices have been widely used in various applications of daily life, such as modern information products including TVs, computers, mobile phones, and etc. In the meanwhile, the display devices are continuously developed and designed towards light, thin, compact, and fashionable. Among existing display devices, the LED display device, especially micro LED display device, has the advantages of low power consumption, high contrast, wide color gamut, high brightness, small size, light weight, thin thickness, and energy saving, so that it has become one of the mainstream display devices.

The micro LEDs utilize the recombination of electron-hole pairs in p-n junctions to generate electromagnetic radiation (e.g. visible light). For example, in a forward-biased p-n junction formed by the direct bandgap materials (e.g. gallium arsenide or gallium nitride), the recombination of electron-hole pairs injected into the depletion region produces electromagnetic radiation. The above-mentioned electromagnetic radiation can be within the wavelength range of visible light or non-visible light, and materials having different bandgaps can be used to manufacture the micro LEDs for producing different color lights.

### SUMMARY

A display device of this disclosure includes a first substrate, a second substrate, an adhesive layer, at least one light-emitting unit, and an intermediate layer. The second substrate is disposed opposite to the first substrate. The adhesive layer is disposed between the first substrate and the second substrate. The light-emitting unit is disposed between the adhesive layer and the first substrate. The light-emitting unit includes at least one light-emitting element, and a surface of the light-emitting element facing toward the adhesive layer is configured with a plurality of micro structures. The intermediate layer is disposed between the adhesive layer and the micro structures. The refractive index of the intermediate layer is greater than 1 and less than the refractive index of the adhesive layer.

A display device of this disclosure includes a first substrate, a second substrate, an adhesive layer, and at least one light-emitting unit. The second substrate is disposed opposite to the first substrate. The adhesive layer is disposed between the first substrate and the second substrate. The light-emitting unit is disposed between the adhesive layer and the first substrate. The light-emitting unit includes at least one light-emitting element, and a surface of the light-emitting element facing toward the adhesive layer is configured with a plurality of micro structures. The refractive index of the adhesive layer is greater than 1 and is less than or equal to 1.4.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a partial sectional view of a display device according to a first embodiment of this disclosure;

FIG. 2 to FIG. 5 are sectional views showing different aspects of the display device as shown in FIG. 1;

FIG. 6 is a partial sectional view of a display device according to a second embodiment of this disclosure; and

FIG. 7 to FIG. 10 are sectional views showing different aspects of the display device as shown in FIG. 6.

### DETAILED DESCRIPTION OF THE DISCLOSURE

The present disclosure will be apparent from the following detailed description, which proceeds with reference to the accompanying drawings, wherein the same references relate to the same elements. It should be understood that the following description provides different embodiments for implementing different aspects of some embodiments of the present disclosure. The specific components and arrangements described below are used to briefly and clearly describe some embodiments of the present disclosure. These embodiments are for illustration and are not intended to limit the scope of the present disclosure. In addition, reference numbers or labels may be repeatedly used in different embodiments. These repetitions are only for the purpose of simply and clearly describing some embodiments of the present disclosure, and do not represent any correlation between the different embodiments and/or structures discussed. Furthermore, when it is mentioned that a certain layer is on or above another layer, the certain layer may directly contact another layer, or one or more other layers or films may be provided between the two layers, so that the certain layer may not directly contact another layer.

Relative terms, such as “lower” and “higher”, or “bottom” and “top”, may be used in following embodiments to describe the relative relationship of one component to another component in the drawings. It will be understood that if the device shown in the drawings is turned upside down, components described as being at the “lower” side would then be at the “higher” side.

The terms “about”, “approximate” and “approximately” usually mean the variation within 20%, preferably within 10%, and more preferably within 5%, 3%, 2%, 1% or 0.5% of a given value or range. The given quantities here are approximate quantities, that is, in the absence of specific description of “about”, “approximate”, or “approximately”, the meaning of “about”, “approximate”, and “approximately” can still be implied.

It will be understood that, although the terms “first”, “second”, “third” and the likes may be used herein to describe various elements, components, regions, layers, and/or portions, these elements, components, regions, layers, and/or portions should not be limited by these terms, and these terms are used to distinguish between different elements, components, regions, layers, and/or portions. Thus, a first element, component, region, layer, and/or portion discussed below could be termed a second element, component, region, layer, and/or portion without departing from the teachings of some embodiments of the present disclosure.

Unless otherwise defined, all terms (including technical and scientific terms) used herein have the same meaning as commonly understood by one of ordinary skill in the related art. It is understood that these terms, such as those defined in commonly used dictionaries, should be interpreted to have a meaning consistent with the relevant technology and the background or content of the present disclosure, and should not be interpreted in an idealized or overly formal way, unless otherwise defined in the embodiments of this disclosure.

Some embodiments of the present disclosure can be understood together with the drawings, and the drawings of the embodiments of the present disclosure are also regarded as part of the description of the embodiments of the present disclosure. It should be understood that the drawings of the embodiments of the present disclosure are not drawn to the actual scale of devices and components. The shapes and thicknesses of embodiments may be exaggerated in the drawings to clearly illustrate features of embodiments of the present disclosure. In addition, the structures and devices in the drawings are illustrated in a schematic manner in order to clearly demonstrate the features of the embodiments of the present disclosure.

In some embodiments of the present disclosure, relative terms such as “lower”, “upper”, “parallel”, “vertical”, “below”, “above”, “top”, “bottom”, etc., shall be understood as the orientations shown in this paragraph and related drawings. This relative terms are for convenience of explanation and does not mean that the device described needs to be manufactured or operated in a specific orientation. Terms related to joining and connecting, such as “connect”, “joint”, etc., unless otherwise defined, can mean that two structures are in direct contact, or they can also mean that the two structures are not in direct contact with one or more additional structures located therebetween. The terms related to joining and connecting two structures can also include the situation that both structures are movable, or both structures are fixed.

To be noted, the term “substrate” in this disclosure may include components formed on a transparent substrate and various film layers covering the substrate, on which any required active components (e.g. transistors) may be formed. In order to simplify the drawings, only a flat substrate is shown.

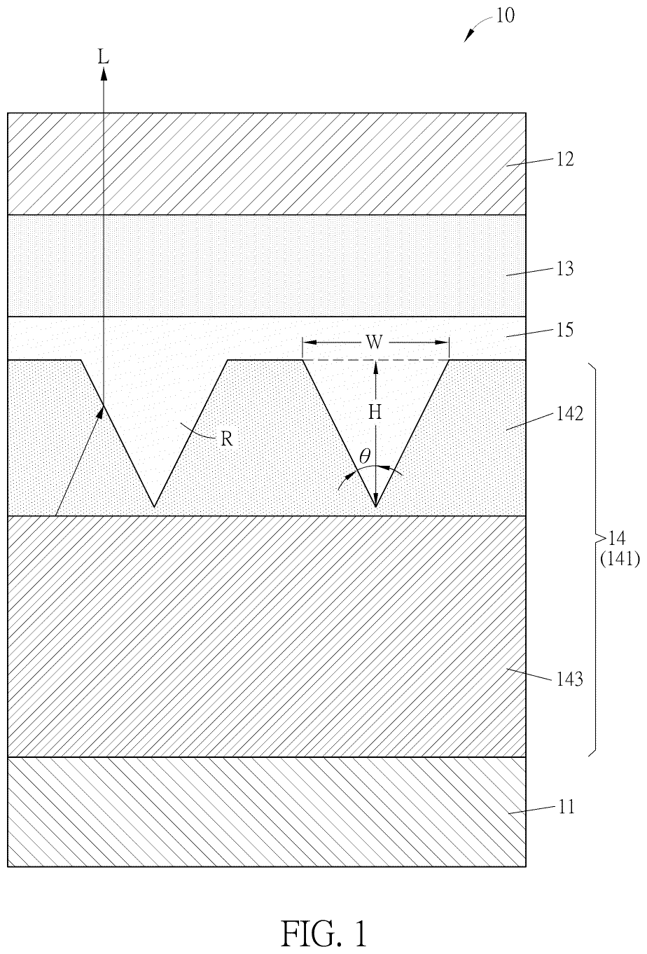

FIG. 1 is a partial sectional view of a display device 10 according to a first embodiment of this disclosure. As shown in FIG. 1, the display device 10 of this embodiment includes a first substrate 11, a second substrate 12, an adhesive layer 13, at least one light-emitting unit 14, and an intermediate layer 15.

In this embodiment, the first substrate 11 may be a substrate including a circuit layer (not shown) that is electrically connected to the light-emitting unit 14. The circuit layer includes, for example, a microprocessor, a memory component, and/or other components. The circuit layer may include different passive components and/or active components, such as thin-film resistors, capacitors (e.g. MIMCAP), inductors, diodes, MOSFET, CMOS transistor, BJT, LDMOS transistor, PMOS transistor, TFT, or other types of transistors. In addition, the first substrate 11 may have a bonding surface, such as the upper surface of the first substrate 11. The first substrate 11 can be a driving substrate that drives the light-emitting unit 14 to emit light, such as a CMOS substrate, a LCOS substrate, a TFT substrate, or other circuit substrate with working circuit, and this disclosure is not limited thereto. In some embodiments, the display device 10 is a micro LED display device, suitable for AR or VR applications, and the length of the first substrate 11 may be, for example but not limited to, less than or equal to 1 inch. The pixels per inch (PPI) of the micro LED display device may be greater than 1,000 or 2,500, and the brightness thereof can exceed 10,000 nits. In other embodiment, the length of the first substrate 11 can be greater than 1 inch, and PPI thereof is not limited.

As shown in FIG. 1, the second substrate 12 is disposed opposite to the first substrate 11, and the adhesive layer 13, the light-emitting unit 14 and the intermediate layer 15 are disposed between the first substrate 11 and the second substrate 12. In this embodiment, the second substrate 12 can be, for example a transparent substrate, so that the light emitted from the light-emitting unit 14 can pass through the second substrate 12 and then be outputted. In another case, the second substrate 12 can be a color filter substrate. That is, a color filter layer is formed on a surface of the second substrate 12. Therefore, the light emitted from the light-emitting unit 14 can pass through the color filter layer and the second substrate 12, and then be outputted. It should be noted that the above descriptions are examples and are not to limit the scope of this disclosure.

Referring to FIG. 1, the adhesive layer 13 is disposed between the first substrate 11 and the second substrate 12, the light-emitting unit 14 is disposed between the adhesive layer 13 and the first substrate 11, and the intermediate layer 15 is disposed between the adhesive layer 13 and the light-emitting unit 14.

In this embodiment, the material of the adhesive layer 13 may include OCA (Optical Clear Adhesive), OCR (Optical Clear Resin, OCR), or other suitable transparent adhesive materials, but the present disclosure is not limited thereto. The refractive index of the adhesive layer 13 is approximately 1.5.

In this embodiment, the light-emitting unit 14 includes at least one light-emitting element 141, and a surface of the light-emitting element 141 facing toward the adhesive layer 13 (or the intermediate layer 15) is configured with a plurality of micro structures 142. For example, the light-emitting element 141 may include an organic light-emitting diode (OLED), a millimeter light-emitting diode (mini LED), a micro light-emitting diode (Micro LED), or a quantum dot light-emitting diode (QDLED), but this disclosure is not limited thereto. In this embodiment, the light-emitting unit 14 includes a plurality of light-emitting elements 141, and the light-emitting elements 141 can be micro LED elements, such as red-light micro LED elements, green-light micro LED elements, and/or blue-light micro LED elements. In addition, the surface of each light-emitting element 141 connected to the intermediate 15 is configured with a plurality of micro structures 142. As shown in FIG. 1, in some embodiments, each light-emitting element 141 includes, for example, a light-emitting portion 143 and a plurality of micro structures 142 formed on one side of the light-emitting portion 143. Generally, the light-emitting portion 143 includes two semiconductor layers and a light-emitting layer sandwiched between the two semiconductor layers. The semiconductor layer can be an element semiconductor, a compound semiconductor, an alloy semiconductor, a metal oxide, an organic semiconductor, or any combination of the above materials. The element semiconductors include amorphous silicon (amorphous-Si), polycrystalline silicon (poly-Si), germanium, etc. The compound semiconductors include gallium nitride (GaN), silicon carbide, gallium arsenide (GaAs), gallium phosphide, indium phosphide, indium arsenide, and/or indium antimonide, etc. The alloy semiconductors include silicon germanium alloy (SiGe), phosphorus arsenide gallium alloy (GaAsP), arsenic aluminum indium alloy (AlInAs), arsenic aluminum gallium alloy (AlGaAs), arsenic indium gallium alloy (GalnAs), phosphorus indium gallium alloy (GaInP), and/or phosphorus arsenic indium gallium alloy (GaInAsP), etc. The metal oxides include indium gallium zinc oxide (IGZO), indium zinc oxide (IZO), indium gallium zinc tin oxide (IGZTO), etc. The organic semiconductors include polycyclic aromatic compounds. Moreover, the semiconductor layers can be any combination of the above-mentioned materials. It should be noted that the above materials are examples and are not to limit the scope of this disclosure.

The light-emitting layer may include a homojunction, a heterojunction, a single-quantum well (SQW), a multiple-quantum well (MQW), or other similar structures. In some embodiments, the light-emitting layer may include non-doped n-type InₓGa₍₁₋ₓ₎N, AlₓIn_{y}Ga_{(1-x-y)}N, or any of other suitable materials. In addition, the light-emitting layer may be a multiple quantum well structure including multiple well layers (e.g. InGaN) and barrier layers (e.g. GaN) arranged in a staggered manner. Furthermore, the formation method of the light-emitting layer may include MOCVD (metal organic chemical vapor deposition), MBE (molecular beam epitaxy), HVPE (hydride vapor phase epitaxy), LPE (liquid phase epitaxy), or any of other appropriate chemical vapor deposition methods. In this embodiment, the light-emitting portion 143 has a multiple quantum well structure.

In this embodiment, the micro structure 142 can be formed by directly processing a surface of the light-emitting part 143 with an etching process. Therefore, the micro structure 142 and one semiconductor layer of the light-emitting portion 143 can be formed of the same material, such as n-GaN. In addition, in other embodiments, the micro structure 142 formed on a surface of the light-emitting portion 143 and the light-emitting part 143 may be different material layers. In this case, a layer of material may be deposited on the light-emitting portion 143 first, and then the layer of material is subjected to an etching process to form the micro structures 142. To be noted, although the intervals between the micro structures 142 shown in FIG. 1 are the same, this disclosure is not limited thereto. In other embodiments, the intervals between the micro structures 142 may be non-fixed or irregular.

In this embodiment, as shown in FIG. 1, each of the micro structures 142, under a sectional view, includes a recess portion R, wherein a depth of each recess portion R is H, and a width of each recess portion R is W. H and W can be defined as:

15°≤tan⁻¹((½W)/H)≤40°.

Moreover, H and W can be further defined as:

15°≤tan⁻¹((½W)/H)≤30°.

Specifically, in this embodiment, the shape of each recess portion R is an inverted triangle. The depth H of the recess portion R defines the height of the inverted triangle, and the width W of the recess portion R defines the base of the inverted triangle. In this case, the included angle θ between the hypotenuse of the inverted triangle (the recess portion R) and the vertical direction is between 15 degrees and 40 degrees, and preferably between 15 degrees and 30 degrees, wherein the included angle θ=tan⁻¹ ((½ W)/H).

In this embodiment, the refractive index of the micro structure 142 is approximately between 2.35 and 2.60 (2.35≤refractive index of micro structure 142≤2.60). The material of the micro structure 142 can be a transparent material, such as ITO (indium tin oxide), TO (tin oxide), IZO (indium zinc oxide), IGZO (indium gallium zinc oxide), ITZO (indium tin zinc oxide), ATO (antimony tin oxide), AZO (antimony zinc oxide), a combination of the above materials, any of other suitable transparent conductive oxide materials, or any suitable semiconductor material (e.g. n-GaN) or polymer material (e.g. optical resin, epoxy resin, silicone resin, etc.). This disclosure is not limited thereto.

As shown in FIG. 1, the intermediate layer 15 is disposed between the adhesive layer 13 and the micro structures 142. The refractive index of the intermediate layer 15 is greater than 1 and less than the refractive index of the adhesive layer 13. In this embodiment, the refractive index of the intermediate layer 15 is greater than 1 and is less than or equal to 1.4. In other words, the refractive index of the intermediate layer 15 is less than the refractive index of the micro structures 142 and is also less than the refractive index of the adhesive layer 13. In this case, the ratio of the refractive index of the intermediate layer 15 to the refractive index of the micro structures 142 is between (1.0/2.60) and (1.4/2.35). In addition, in this embodiment, the material of the intermediate layer 15 may include OCA (optical clear adhesive), OCR (optical clear resin), or any of other suitable transparent adhesive materials (e.g. photoresist materials), and this disclosure is not limited thereto.

To be noted, in this embodiment, the refractive index of the intermediate layer 15 is less than the refractive index of the micro structures 142 and is less than the refractive index of the adhesive layer 13, and the included angle θ is between 15 degrees and 40 degrees (especially the included angle θ is between 15 degrees and 30 degrees). Based on these features and designs, the extraction efficiency of the light L, which is emitted from the light-emitting portion 143 and then passes through the micro structures 142, the intermediate layer 15, the adhesive layer 13 and the second substrate 12 in sequence, can be effectively improved, thereby increasing the overall light output efficiency of the display device 10. During actual testing, when the included angle θ is between 15 degrees and 40 degrees, the overall brightness of the display device 10 will be improved in different levels. In particular, when the included angle θ is between 15 degrees and 30 degrees, the overall brightness of the device 10 will reach a better value, which is close to the situation that the light emitted from the light-emitting element directly enters the air medium.

In addition, in other embodiments of this disclosure, the display device can be a color display device, which can be defined with a plurality of pixels, and each pixel may include multiple sub-pixels, such as a red sub-pixel, a green sub-pixel and a blue sub-pixel. In this disclosure, each light-emitting unit defines a pixel, and the multiple light-emitting elements in one light-emitting unit define the multiple sub-pixels in the corresponding pixel. Each sub-pixel can be composed of a corresponding light-emitting element, or include a corresponding light-emitting element as well as at least one of a corresponding color filter layer (or color filter portion), a light conversion layer (or a light conversion portion), a diffusion layer (or a diffusion portion), etc., or any combination thereof. This disclosure is not limited thereto.

The structure configurations of the display devices in different aspects of the first embodiment of this disclosure will be illustrated below with reference to the drawings. To be noted, the following aspects are for illustrations, and the disclosure is not limited thereto.

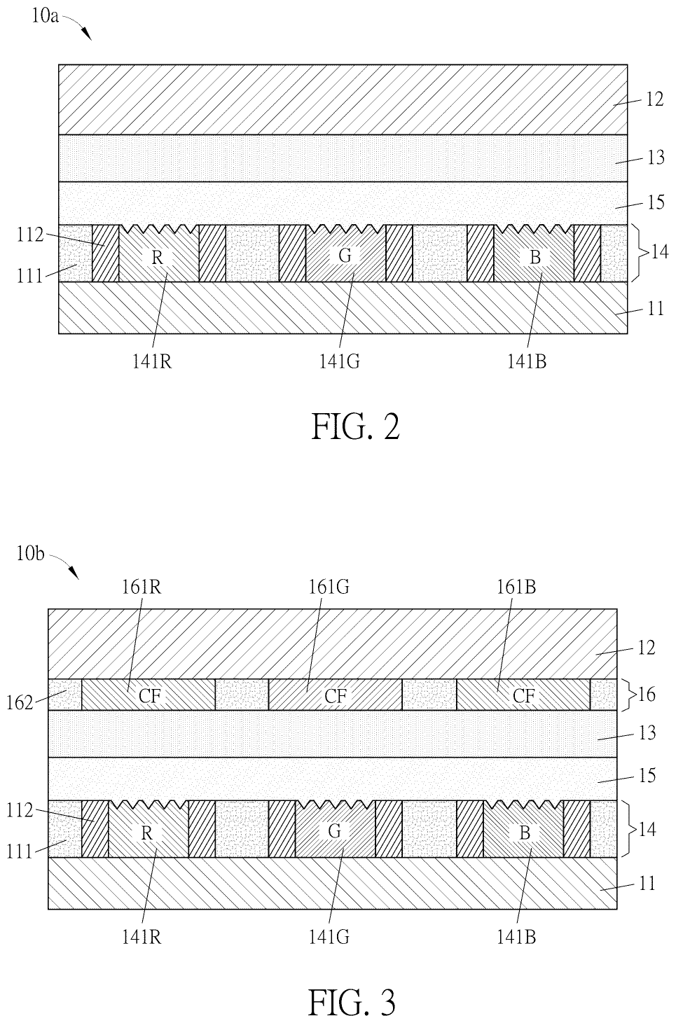

FIG. 2 is a sectional view showing an aspect of the display device 10 as shown in FIG. 1. In this aspect, as shown in FIG. 2, the display device 10a includes a first substrate 11, a second substrate 12, an adhesive layer 13, at least one light-emitting unit 14 and an intermediate layer 15. The second substrate 12 is disposed opposite to the first substrate 11. The adhesive layer 13 is disposed between the first substrate 11 and the second substrate 12. The light-emitting unit 14 is disposed between the adhesive layer 13 and the first substrate 11. The light-emitting unit 14 includes three light-emitting elements, such as a red light-emitting element 141R, a green light-emitting element 141G and a blue light-emitting element 141B. For example, the red light-emitting element 141R can be a red-light LED, the green light-emitting element 141G can be a green-light LED, and the blue light-emitting element 141B can be a blue-light LED. Therefore, the display device 10a can emit colored light to output colorful images. The surface of each light-emitting element 141R, 141G or 141B facing toward the adhesive layer 13 is configured with a plurality of micro structures 142, and the intermediate layer 15 is disposed between the adhesive layer 13 and the micro structures 142. The refractive index of the intermediate layer 15 is greater than 1, and can be, for example, between 1 and 1.4. In addition, the refractive index of the intermediate layer 15 is less than the refractive index of the adhesive layer 13 and is also less than the refractive index of the micro structures 142.

Moreover, in this aspect, a pixel define layer (PDL) 111 and an underfill layer 112 can be further formed on the first substrate 11. The pixel define layer 111 is formed with a plurality of accommodating spaces for accommodating the light-emitting elements 141R, 141G and 141B, respectively. The underfill layers 112 are respectively disposed in the accommodating spaces and surround the light-emitting elements 141R, 141G and 141B, which are disposed in the accommodating spaces. In some embodiments, a layer of material, such as an organic photoresist material layer, for forming the pixel define layer 111 can be applied on the first substrate 11 by, for example, spraying process, and then the layer of material can be patterned by a photolithography process so as to form a structure including multiple accommodating spaces as shown in FIG. 2. In addition, a reflective layer (not shown) may be formed on the pixel define layer 111 to improve the light output efficiency, but the disclosure is not limited thereto. After the light-emitting elements 141R, 141G and 141B are respectively disposed in the accommodating spaces, the underfill material can be provided around the light-emitting elements 141R, 141G and 141B for forming the underfill layer 112. The underfill material can be, for example, silicone, epoxy resin, polymethyl methacrylate, polycarbonate, or any of other suitable materials. To be noted, the above descriptions are for an illustration and are not intended to limit the scope of this disclosure, and this disclosure is not limited thereto.

FIG. 3 is a sectional view showing another aspect of the display device 10 as shown in FIG. 1. The component configurations and connections of the display device 10b of FIG. 3 are mostly the same as those of the display device 10a of FIG. 2. Unlike the display device 10a, the display device 10b of this aspect further includes a color filter layer 16, which is disposed on one side of the second substrate 12 facing toward the light-emitting unit 14. In this aspect, the color filter layer 16 includes a red-light filter portion 161R, a green-light filter portion 161G, and a blue-light filter portion 161B. The red-light filter portion 161R, the green-light filter portion 161G and the blue-light filter portion 161B respectively overlap with the red light-emitting element 141R, the green light-emitting element 141G and the blue light-emitting element 141B. Specifically, in order to form the color filter layer 16 on the second substrate 12, a layer of bank material, such as an organic photoresist material layer, can be applied on the second substrate 12 by, for example, spraying process, and the layer of bank material can be patterned by a photolithography process so as to define a patterned structure including multiple spaces for forming the color filter portions. Afterwards, additional spraying processes and photolithography processes can be applied to form the red-light filter portion 161R, the green-light filter portion 161G and the blue-light filter portion 161B. In this case, the remaining bank material can form the banks 162 between the color filter portions 161R, 161G and 161B. In one aspect, the banks 162 can be a black matrix (BM) layer. To be noted, the above descriptions are for an illustration and are not intended to limit the scope of this disclosure, and this disclosure is not limited thereto.

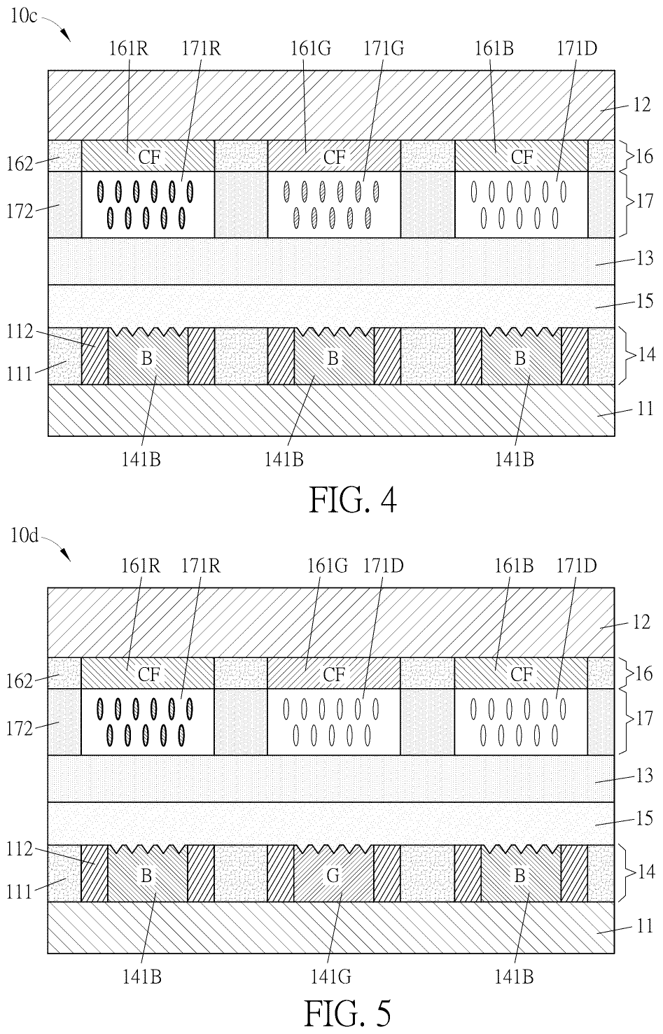

FIG. 4 is a sectional view showing another aspect of the display device 10 as shown in FIG. 1. The component configurations and connections of the display device 10c of FIG. 4 are mostly the same as those of the display device 10b of FIG. 3. Unlike the display device 10b, the display device 10c of FIG. 4 further includes an optical layer 17, which is provided at one side of the color filter layer 16 facing toward the light-emitting unit 14. In the display device 10c, the light-emitting unit 14 includes three light-emitting elements, which emit the same color light, such as three blue light-emitting elements 141B. In this aspect, the first blue light-emitting element 141B corresponds to a first light conversion portion 171R of the optical layer 17 and corresponds to the red-light filter portion 161R of the color filter layer 16. The first light conversion portion 171R can convert the blue light emitted by the first blue light-emitting element 141B into red light, and the red light can pass through the red-light filter portion 161R and the second substrate 12 and then be outputted from the display device 10c. The second blue light-emitting element 141B corresponds to a second light conversion portion 171G of the optical layer 17 and corresponds to the green-light filter portion 161G of the color filter layer 16. The second light conversion portion 171G can convert the blue light emitted by the second blue light-emitting element 141B into green light, and the green light can pass through the green-light filter portion 161G and the second substrate 12 and then be outputted from the display device 10c. The third blue light-emitting element 141B corresponds to a light diffusion portion 171D of the optical layer 17 and the blue-light filter portion 161B of the color filter layer 16. The blue light emitted by the third blue light-emitting element 141B can pass through the light diffusion portion 171D, the blue-light filter portion 161B and the second substrate 12 sequentially, and then be outputted from the display device 10c. Specifically, in order to form the optical layer 17 on the color filter layer 16, a layer of bank material, such as an organic photoresist material layer, can be applied on the color filter layer 16 by, for example, spraying process, and the layer of bank material can be patterned by a photolithography process so as to define a patterned structure including multiple spaces for forming the light diffusion portion and the light conversion portions. Afterwards, additional spraying processes and photolithography processes can be applied to form the first light conversion portion 171R, the second light conversion portion 171G and the light diffusion portion 171D. In this case, the remaining bank material can form the banks 172 between the first light conversion portion 171R, the second light conversion portion 171G and the light diffusion portion 171D. To be noted, the above descriptions are for an illustration and are not intended to limit the scope of this disclosure, and this disclosure is not limited thereto. In addition, the light conversion portions, such as the above-mentioned first light conversion portion 171R and second light conversion portion 171G, may include, for example but not limited to, particle-type quantum dots. The material of the quantum dots may include CdSe, InP, SiO₂, ZrO₂, TiO₂, Al₂O₃, In₂O₃, ZnO, SnO₂, Sb₂O₃, or any of other suitable materials, or any combination of the above-mentioned materials, but this disclosure is not limited thereto. The light diffusion portion of this embodiment, such as the above-mentioned light diffusion portion 171D, may include, for example but not limited to, light diffusion particles, and the material of the light diffusion particles includes, for example, TiO₂, but this disclosure is not limited thereto.

FIG. 5 is a sectional view showing another aspect of the display device 10 as shown in FIG. 1. The component configurations and connections of the display device 10d of FIG. 5 are mostly the same as those of the display device 10c of FIG. 4. Unlike the display device 10c, the light-emitting unit 14 of the display device 10d of FIG. 5 includes two blue light-emitting elements 141B and one green light-emitting element 141G. In this aspect, the first blue light-emitting element 141B corresponds to a light conversion portion 171R of the optical layer 17 and corresponds to the red-light filter portion 161R of the color filter layer 16. The light conversion portion 171R can convert the blue light emitted by the first blue light-emitting element 141B into red light, and the red light can pass through the red-light filter portion 161R and the second substrate 12 and then be outputted from the display device 10d. The green light-emitting element 141G corresponds to a first light diffusion portion 171D of the optical layer 17 and corresponds to the green-light filter portion 161G of the color filter layer 16. The green light emitted by the green light-emitting element 141G can pass through the first light diffusion portion 171D, the green-light filter portion 161G and the second substrate 12 sequentially, and then be outputted from the display device 10d. The second blue light-emitting element 141B corresponds to a light diffusion portion 171D of the optical layer 17 and the blue-light filter portion 161B of the color filter layer 16. The blue light emitted by the second blue light-emitting element 141B can pass through the light diffusion portion 171D, the blue-light filter portion 161B and the second substrate 12 sequentially, and then be outputted from the display device 10d. To be noted, the above descriptions are for an illustration and are not intended to limit the scope of this disclosure, and this disclosure is not limited thereto.

In summary, the display device of this embodiment includes a first substrate, a second substrate, an adhesive layer, at least one light-emitting unit, and an intermediate layer. The second substrate is disposed opposite to the first substrate. The adhesive layer is disposed between the first substrate and the second substrate. The light-emitting unit is disposed between the adhesive layer and the first substrate. The light-emitting unit includes at least one light-emitting element, and a surface of the light-emitting element facing toward the adhesive layer is configured with a plurality of micro structures. The intermediate layer is disposed between the adhesive layer and the micro structures. The refractive index of the intermediate layer is greater than 1 and less than the refractive index of the adhesive layer, and the included angle θ between the hypotenuse of the recess portion of the micro structure and the vertical direction is between 15 degrees and 40 degrees. In the display device of this embodiment, the refractive index of the intermediate layer is less than the refractive index of the micro structures and is less than the refractive index of the adhesive layer, and the included angle θ is between 15 degrees and 40 degrees. Based on these features and designs, the light emitted from each light-emitting element sequentially passes through the micro structures, the intermediate layer, the adhesive layer and the second substrate, and is then outputted from the display device. In some cases, the light emitted from each light-emitting element may further pass through the color filter layer or through the color filter layer and the optical layer. Accordingly, the extraction efficiency of the outputted light can be effectively improved, thereby increasing the overall light output efficiency of the display device.

To be noted, in the case without the limitation of the included angle θ, when the refractive index of the intermediate layer is less than the refractive index of the micro structures and is also less than the refractive index of the adhesive layer, the light emitted from each light-emitting element sequentially passes through the micro structures, the intermediate layer, the adhesive layer and the second substrate, and is then outputted from the display device. In some cases, the light emitted from each light-emitting element may further pass through the color filter layer or through the color filter layer and the optical layer. The extraction efficiency of the outputted light can still be effectively improved, thereby increasing the overall light output efficiency of the display device.

In some cases, when the display device has the limitation of the included angle θ, which is between 15 degrees and 40 degrees, but does not include the intermediate layer, if the refractive index of the adhesive layer is modified to be equal to the refractive index of the intermediate layer 15 of the above embodiments, the overall light output efficiency of the display device can still be increased based on the above limitation of included angle θ and the modification of the adhesive layer.

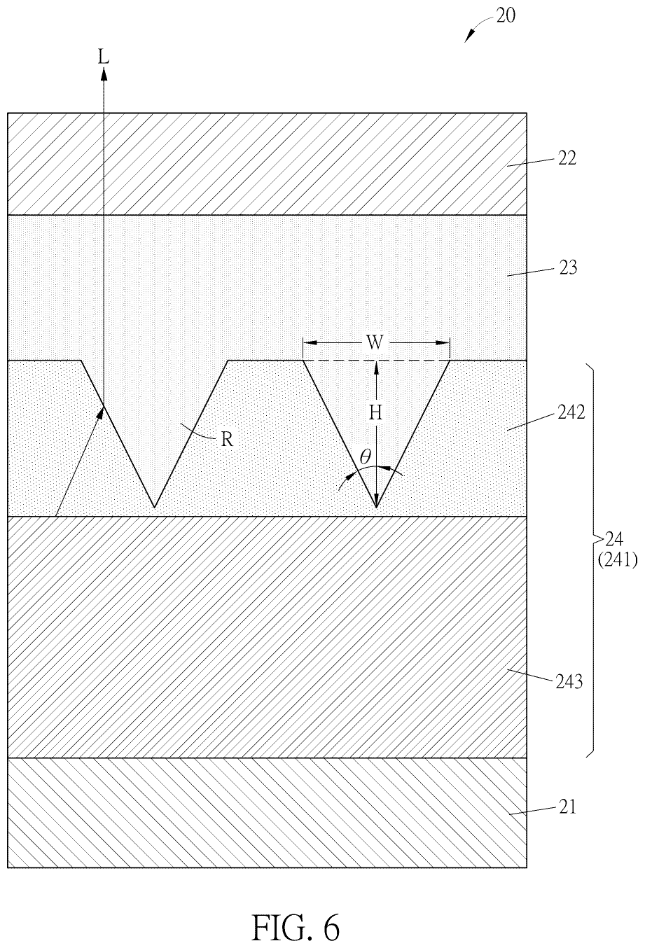

FIG. 6 is a partial sectional view of a display device 20 according to a second embodiment of this disclosure. As shown in FIG. 6, the display device 20 of this embodiment includes a first substrate 21, a second substrate 22, an adhesive layer 23, and at least one light-emitting unit 24.

In this embodiment, the first substrate 21 can be a substrate including a circuit layer (not shown) that is electrically connected to the light-emitting unit 24. The first substrate 21 can refer to the first substrate 11 of the previous embodiment, so the detailed description thereof will be omitted.

As shown in FIG. 6, the second substrate 22 is disposed opposite to the first substrate 21, and the adhesive layer 23 and the light-emitting unit 24 are disposed between the first substrate 21 and the second substrate 22. The second substrate 22 can refer to the second substrate 12 of the previous embodiment, so the detailed description thereof will be omitted.

Referring to FIG. 6, the adhesive layer 23 is disposed between the first substrate 21 and the second substrate 22, and the light-emitting unit 24 is disposed between the adhesive layer 23 and the first substrate 21. To be noted, the display device 20 of this embodiment does not include the intermediate layer, so the adhesive layer 23 is directly disposed on the light-emitting unit 24. In this embodiment, the refractive index of the adhesive layer 23 is modified to be equal to the refractive index of the intermediate layer 15 of the previous embodiment, such as to be greater than 1 and be less than or equal to 1.4. According to this design, the light output efficiency of the display device 20 can be improved. The adhesive layer 23 and the light-emitting unit 24 can refer to the adhesive layer 13 and the light-emitting unit 14 of the previous embodiment, so the detailed description thereof will be omitted.

To be noted, the light-emitting unit 24 includes at least one light-emitting element 241, and a surface of the light-emitting element 241 facing toward the adhesive layer 23 is configured with a plurality of micro structures 242. For example, the light-emitting element 241 may include an organic light-emitting diode (OLED), a millimeter light-emitting diode (mini LED), a micro light-emitting diode (Micro LED), or a quantum dot light-emitting diode (QDLED), but this disclosure is not limited thereto. In this embodiment, the light-emitting unit 24 includes a plurality of light-emitting elements 241, and the light-emitting elements 241 can be micro LED elements, such as red-light micro LED elements, green-light micro LED elements, and/or blue-light micro LED elements. In this embodiment, each light-emitting element 241 includes, for example, a light-emitting portion 243 and a plurality of micro structures 242 formed on one side of the light-emitting portion 243. As shown in FIG. 6, each of the micro structures 242, under a sectional view, includes a recess portion R, wherein a depth of each recess portion R is H, and a width of each recess portion R is W. H and W can be defined as:

15°≤tan⁻¹((½W)/H)≤40°.

Moreover, H and W can be further defined as:

15°≤tan⁻¹((½W)/H)≤30°.

Specifically, in this embodiment, the shape of each recess portion R is an inverted triangle. The depth H of the recess portion R defines the height of the inverted triangle, and the width W of the recess portion R defines the base of the inverted triangle. In this case, the included angle θ between the hypotenuse of the inverted triangle (the recess portion R) and the vertical direction is between 15 degrees and 40 degrees, and preferably between 15 degrees and 30 degrees, wherein the included angle θ=tan⁻¹ ((½ W)/H). In this embodiment, the refractive index of the micro structure 242 is approximately between 2.35 and 2.60 (2.35≤refractive index of micro structure 242≤2.60).

To be noted, in this embodiment, the included angle θ is between 15 degrees and 40 degrees, so that the extraction efficiency of the light L, which is emitted from the light-emitting portion 243 and then passes through the micro structures 242, the adhesive layer 23 and the second substrate 22 in sequence, can be effectively improved, thereby increasing the overall light output efficiency of the display device 20.

The structure configurations of the display devices in different aspects of the second embodiment of this disclosure will be illustrated below with reference to the drawings. To be noted, the following aspects are for illustrations, and the disclosure is not limited thereto.

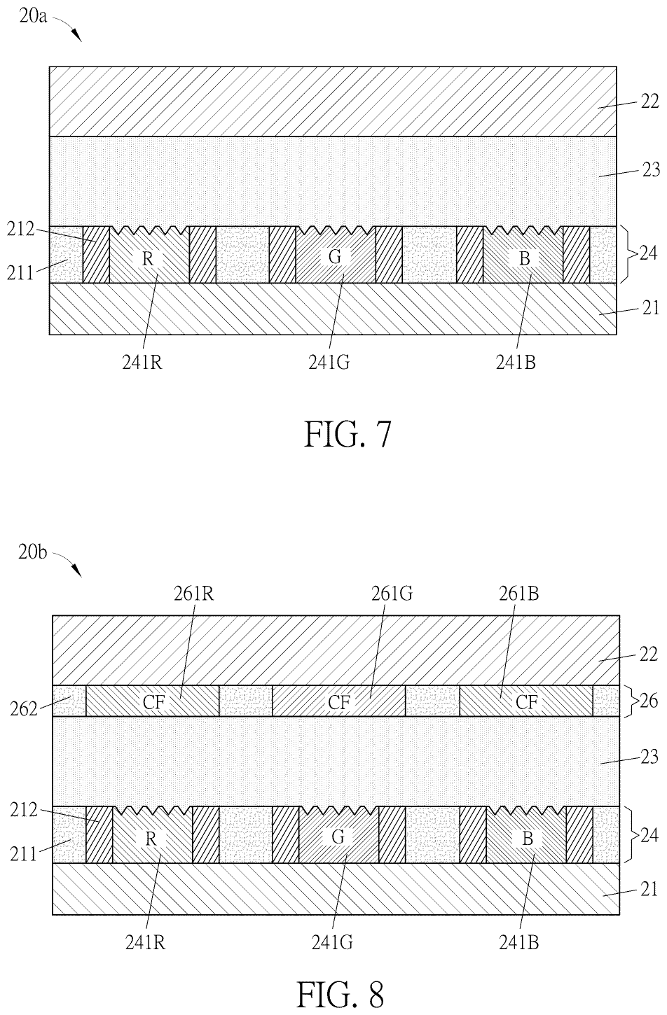

FIG. 7 is a sectional view showing an aspect of the display device 20 as shown in FIG. 6. In this aspect, as shown in FIG. 7, the display device 20a includes a first substrate 21, a second substrate 22, an adhesive layer 23 and at least one light-emitting unit 24. The second substrate 22 is disposed opposite to the first substrate 21. The adhesive layer 23 is disposed between the first substrate 21 and the second substrate 22. The light-emitting unit 24 is disposed between the adhesive layer 23 and the first substrate 21. The light-emitting unit 24 includes three light-emitting elements, such as a red light-emitting element 241R, a green light-emitting element 241G and a blue light-emitting element 241B. For example, the red light-emitting element 241R can be a red-light LED, the green light-emitting element 241G can be a green-light LED, and the blue light-emitting element 241B can be a blue-light LED. Therefore, the display device 20a can emit colored light to output colorful images. The surface of each light-emitting element 241R, 241G or 241B facing toward the adhesive layer 23 is configured with a plurality of micro structures 242. Each micro structure 242 includes a recess portion R, wherein a depth of each recess portion R is H, and a width of each recess portion R is W. The included angle θ(=tan⁻¹ ((½ W)/H)) between the hypotenuse of the recess portion R and the vertical direction is between 15 degrees and 40 degrees, and preferably between 15 degrees and 30 degrees.

Moreover, in this aspect, a pixel define layer (PDL) 211 and an underfill layer 212 can be further formed on the first substrate 21. The pixel define layer 211 is formed with a plurality of accommodating spaces for accommodating the light-emitting elements 241R, 241G and 241B, respectively. The underfill layers 212 are respectively disposed in the accommodating spaces and surround the light-emitting elements 241R, 241G and 241B, which are disposed in the accommodating spaces. In some embodiments, a layer of material, such as an organic photoresist material layer, for forming the pixel define layer 211 can be applied on the first substrate 21 by, for example, spraying process, and then the layer of material can be patterned by a photolithography process so as to form a structure including multiple accommodating spaces as shown in FIG. 7. In addition, a reflective layer (not shown) may be formed on the pixel define layer 211 to improve the light output efficiency, but the disclosure is not limited thereto. After the light-emitting elements 241R, 241G and 241B are respectively disposed in the accommodating spaces, the underfill material can be provided around the light-emitting elements 241R, 241G and 241B for forming the underfill layer 212. The underfill material can be, for example, silicone, epoxy resin, polymethyl methacrylate, polycarbonate, or any of other suitable materials. To be noted, the above descriptions are for an illustration and are not intended to limit the scope of this disclosure, and this disclosure is not limited thereto.

FIG. 8 is a sectional view showing another aspect of the display device 20 as shown in FIG. 6. The component configurations and connections of the display device 20b of FIG. 8 are mostly the same as those of the display device 20a of FIG. 7. Unlike the display device 20a, the display device 20b of this aspect further includes a color filter layer 26, which is disposed on one side of the second substrate 22 facing toward the light-emitting unit 24. In this aspect, the color filter layer 26 includes a red-light filter portion 261R, a green-light filter portion 261G, and a blue-light filter portion 261B. The red-light filter portion 261R, the green-light filter portion 261G and the blue-light filter portion 261B respectively overlap with the red light-emitting element 241R, the green light-emitting element 241G and the blue light-emitting element 241B. Specifically, in order to form the color filter layer 26 on the second substrate 22, a layer of bank material, such as an organic photoresist material layer, can be applied on the second substrate 22 by, for example, spraying process, and the layer of bank material can be patterned by a photolithography process so as to define a patterned structure including multiple spaces for forming the color filter portions. Afterwards, additional spraying processes and photolithography processes can be applied to form the red-light filter portion 261R, the green-light filter portion 261G and the blue-light filter portion 261B. In this case, the remaining bank material can form the banks 262 between the color filter portions 261R, 261G and 261B. In one aspect, the banks 262 can be a black matrix (BM) layer. To be noted, the above descriptions are for an illustration and are not intended to limit the scope of this disclosure, and this disclosure is not limited thereto.

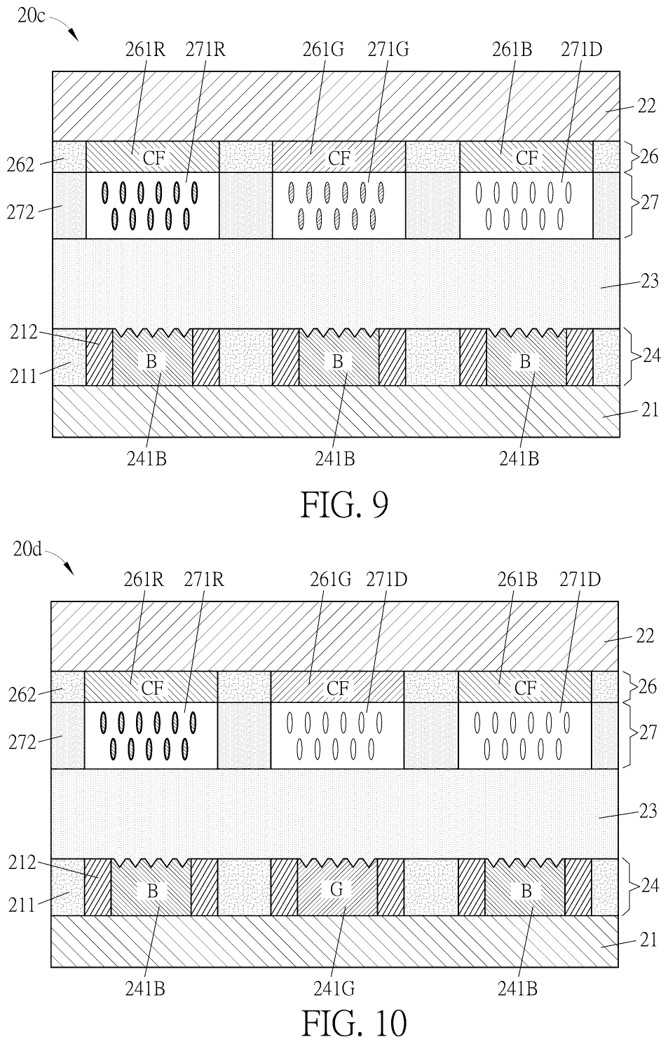

FIG. 9 is a sectional view showing another aspect of the display device 20 as shown in FIG. 6. The component configurations and connections of the display device 20c of FIG. 9 are mostly the same as those of the display device 20b of FIG. 8. Unlike the display device 20b, the display device 20c of FIG. 9 further includes an optical layer 27, which is provided at one side of the color filter layer 26 facing toward the light-emitting unit 24. In the display device 20c, the light-emitting unit 24 includes three light-emitting elements, which emit the same color light, such as three blue light-emitting elements 241B. In this aspect, the first blue light-emitting element 241B corresponds to a first light conversion portion 271R of the optical layer 27 and corresponds to the red-light filter portion 261R of the color filter layer 26. The first light conversion portion 271R can convert the blue light emitted by the first blue light-emitting element 241B into red light, and the red light can pass through the red-light filter portion 261R and the second substrate 22 and then be outputted from the display device 20c. The second blue light-emitting element 241B corresponds to a second light conversion portion 271G of the optical layer 27 and corresponds to the green-light filter portion 261G of the color filter layer 26. The second light conversion portion 271G can convert the blue light emitted by the second blue light-emitting element 241B into green light, and the green light can pass through the green-light filter portion 261G and the second substrate 22 and then be outputted from the display device 20c. The third blue light-emitting element 241B corresponds to a light diffusion portion 271D of the optical layer 27 and the blue-light filter portion 261B of the color filter layer 26. The blue light emitted by the third blue light-emitting element 241B can pass through the light diffusion portion 271D, the blue-light filter portion 261B and the second substrate 22 sequentially, and then be outputted from the display device 20c. Specifically, in order to form the optical layer 27 on the color filter layer 26, a layer of bank material, such as an organic photoresist material layer, can be applied on the color filter layer 26 by, for example, spraying process, and the layer of bank material can be patterned by a photolithography process so as to define a patterned structure including multiple spaces for forming the light diffusion portion and the light conversion portions. Afterwards, additional spraying processes and photolithography processes can be applied to form the first light conversion portion 271R, the second light conversion portion 271G and the light diffusion portion 271D. In this case, the remaining bank material can form the banks 272 between the first light conversion portion 271R, the second light conversion portion 271G and the light diffusion portion 271D. To be noted, the above descriptions are for an illustration and are not intended to limit the scope of this disclosure, and this disclosure is not limited thereto. In addition, the light conversion portions, such as the above-mentioned first light conversion portion 271R and second light conversion portion 271G, may include, for example but not limited to, particle-type quantum dots. The material of the quantum dots may include CdSe, InP, SiO₂, ZrO₂, TiO₂, Al₂O₃, In₂O₃, ZnO, SnO₂, Sb₂O₃, or any of other suitable materials, or any combination of the above-mentioned materials, but this disclosure is not limited thereto. The light diffusion portion of this embodiment, such as the above-mentioned light diffusion portion 271D, may include, for example but not limited to, light diffusion particles, and the material of the light diffusion particles includes, for example, TiO₂, but this disclosure is not limited thereto.

FIG. 10 is a sectional view showing another aspect of the display device 20 as shown in FIG. 6. The component configurations and connections of the display device 20d of FIG. 10 are mostly the same as those of the display device 20c of FIG. 9. Unlike the display device 20c, the light-emitting unit 24 of the display device 20d of FIG. 10 includes two blue light-emitting elements 241B and one green light-emitting element 241G. In this aspect, the first blue light-emitting element 241B corresponds to a light conversion portion 271R of the optical layer 27 and corresponds to the red-light filter portion 261R of the color filter layer 26. The light conversion portion 271R can convert the blue light emitted by the first blue light-emitting element 241B into red light, and the red light can pass through the red-light filter portion 261R and the second substrate 22 and then be outputted from the display device 20d. The green light-emitting element 241G corresponds to a first light diffusion portion 271D of the optical layer 27 and corresponds to the green-light filter portion 261G of the color filter layer 26. The green light emitted by the green light-emitting element 241G can pass through the first light diffusion portion 271D, the green-light filter portion 261G and the second substrate 22 sequentially, and then be outputted from the display device 20d. The second blue light-emitting element 241B corresponds to a light diffusion portion 271D of the optical layer 27 and the blue-light filter portion 261B of the color filter layer 26. The blue light emitted by the second blue light-emitting element 241B can pass through the light diffusion portion 271D, the blue-light filter portion 261B and the second substrate 22 sequentially, and then be outputted from the display device 20d. To be noted, the above descriptions are for an illustration and are not intended to limit the scope of this disclosure, and this disclosure is not limited thereto.

In summary, the display device of this embodiment includes a first substrate, a second substrate, an adhesive layer and at least one light-emitting unit. The second substrate is disposed opposite to the first substrate. The adhesive layer is disposed between the first substrate and the second substrate, and the refractive index of the adhesive layer is greater than 1 and is less than or equal to 1.4. The light-emitting unit is disposed between the adhesive layer and the first substrate. The light-emitting unit includes at least one light-emitting element, and a surface of the light-emitting element facing toward the adhesive layer is configured with a plurality of micro structures. The included angle θ between the hypotenuse of the recess portion of the micro structure and the vertical direction is between 15 degrees and 40 degrees. In the display device of this embodiment, the refractive index of the intermediate layer is less than the refractive index of the micro structures and is less than the refractive index of the adhesive layer, and the included angle θ is between 15 degrees and 40 degrees. Based on these features and designs, the light emitted from each light-emitting element sequentially passes through the micro structures, the adhesive layer and the second substrate, and is then outputted from the display device. In some cases, the light emitted from each light-emitting element may further pass through the color filter layer or through the color filter layer and the optical layer. Accordingly, the extraction efficiency of the outputted light can be effectively improved, thereby increasing the overall light output efficiency of the display device.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A display device, comprising:
a first substrate;
a second substrate disposed opposite to the first substrate;
an adhesive layer disposed between the first substrate and the second substrate;
at least a light-emitting unit disposed between the adhesive layer and the first substrate, wherein the light-emitting unit comprises at least a light-emitting element, and a surface of the light-emitting element facing toward the adhesive layer is configured with a plurality of micro structures; and
an intermediate layer disposed between the adhesive layer and the micro structures;
wherein, a refractive index of the intermediate layer is greater than 1 and less than a refractive index of the adhesive layer.

2. The display device of claim 1, wherein the refractive index of the intermediate layer is greater than 1 and is less than or equal to 1.4.

3. The display device of claim 1, wherein at least one of the micro structures, under a sectional view, comprises a recess portion, a depth of the recess portion is H, a width of the recess portion is W, and H and W are defined as:
15°≤tan⁻¹((½W)/H)≤40°.

4. The display device of claim 3, wherein H and W are further defined as:
15°≤tan⁻¹((½W)/H)≤30°.

5. The display device of claim 3, wherein a shape of the recess portion is an inverted triangle, the depth of the recess portion defines a height of the inverted triangle, and the width of the recess portion defines a base of the inverted triangle.

6. The display device of claim 1, wherein the first substrate comprises a pixel define layer and an underfill layer, the pixel define layer is formed with at least an accommodating space, the light-emitting element is disposed in the accommodating space, and the under fill layer is filled in the accommodating space and surrounds the light-emitting element.

7. The display device of claim 1, wherein the second substrate comprises at least a color filter layer, at least a light conversion layer, and/or at least a diffusion layer, and the color filter layer, the light conversion layer, or the diffusion layer correspondingly overlaps with the light-emitting element.

8. The display device of claim 1, wherein the light-emitting unit at least comprises a red light-emitting element, a green light-emitting element and a blue light-emitting element, the second substrate comprises a color filter layer, the color filter layer is provided at one side of the second substrate facing toward the light-emitting unit, and the color filter layer comprises a red-light filter portion correspondingly overlapping with the red light-emitting element, a green-light filter portion correspondingly overlapping with the green light-emitting element, and a blue-light filter portion correspondingly overlapping with the blue light-emitting element.

9. The display device of claim 1, wherein the light-emitting unit at least comprises a first blue light-emitting element, a second blue light-emitting element and a third blue light-emitting element, the second substrate comprises a color filter layer and an optical layer, the color filter layer and the optical layer are provided at one side of the second substrate facing toward the light-emitting unit, the optical layer is disposed between the color filter layer and a light-emitting unit, the color filter layer comprises a red-light filter portion, a green-light filter portion and a blue-light filter portion, the optical layer comprises a first light conversion portion, a second light conversion portion and a light diffusion portion, the red-light filter portion and the first light conversion portion correspondingly overlap with the first blue light-emitting element, the green-light filter portion and the second light conversion portion correspondingly overlap with the second blue light-emitting element, and the blue-light filter portion and the light diffusion portion correspondingly overlap with the third blue light-emitting element.

10. The display device of claim 1, wherein the light-emitting unit at least comprises a first blue light-emitting element, a green light-emitting element and a second blue light-emitting element, the second substrate comprises a color filter layer and an optical layer, the color filter layer and the optical layer are provided at one side of the second substrate facing toward the light-emitting unit, the optical layer is disposed between the color filter layer and a light-emitting unit, the color filter layer comprises a red-light filter portion, a green-light filter portion and a blue-light filter portion, the optical layer comprises a light conversion portion, a first light diffusion portion and a second light diffusion portion, the red-light filter portion and the light conversion portion correspondingly overlap with the first blue light-emitting element, the green-light filter portion and the first light diffusion portion correspondingly overlap with the green light-emitting element, and the blue-light filter portion and the second light diffusion portion correspondingly overlap with the second blue light-emitting element.

11. A display device, comprising:
a first substrate;
a second substrate disposed opposite to the first substrate;
an adhesive layer disposed between the first substrate and the second substrate; and
at least a light-emitting unit disposed between the adhesive layer and the first substrate, wherein the light-emitting unit comprises at least a light-emitting element, and a surface of the light-emitting element facing toward the adhesive layer is configured with a plurality of micro structures;
wherein, a refractive index of the adhesive layer is greater than 1 and is less than or equal to 1.4.

12. The display device of claim 11, further comprising:
an intermediate layer disposed between the adhesive layer and the micro structures;
wherein, a refractive index of the intermediate layer is greater than 1 and less than the refractive index of the adhesive layer.

13. The display device of claim 11, wherein at least one of the micro structures, under a sectional view, comprises a recess portion, a depth of the recess portion is H, a width of the recess portion is W, and H and W are defined as:
15°≤tan⁻¹((½W)/H)≤40°.

14. The display device of claim 13, wherein H and W are further defined as:
15°≤tan⁻¹((½W)/H)≤30°.

15. The display device of claim 13, wherein a shape of the recess portion is an inverted triangle, the depth of the recess portion defines a height of the inverted triangle, and the width of the recess portion defines a base of the inverted triangle.

16. The display device of claim 11, wherein the first substrate comprises a pixel define layer and an underfill layer, the pixel define layer is formed with at least an accommodating space, the light-emitting element is disposed in the accommodating space, and the under fill layer is filled in the accommodating space and surrounds the light-emitting element.

17. The display device of claim 11, wherein the second substrate comprises at least a color filter layer, at least a light conversion layer, and/or at least a diffusion layer, and the color filter layer, the light conversion layer, or the diffusion layer correspondingly overlaps with the light-emitting element.

18. The display device of claim 11, wherein the light-emitting unit at least comprises a red light-emitting element, a green light-emitting element and a blue light-emitting element, the second substrate comprises a color filter layer, the color filter layer is provided at one side of the second substrate facing toward the light-emitting unit, and the color filter layer comprises a red-light filter portion correspondingly overlapping with the red light-emitting element, a green-light filter portion correspondingly overlapping with the green light-emitting element, and a blue-light filter portion correspondingly overlapping with the blue light-emitting element.

19. The display device of claim 11, wherein the light-emitting unit at least comprises a first blue light-emitting element, a second blue light-emitting element and a third blue light-emitting element, the second substrate comprises a color filter layer and an optical layer, the color filter layer and the optical layer are provided at one side of the second substrate facing toward the light-emitting unit, the optical layer is disposed between the color filter layer and a light-emitting unit, the color filter layer comprises a red-light filter portion, a green-light filter portion and a blue-light filter portion, the optical layer comprises a first light conversion portion, a second light conversion portion and a light diffusion portion, the red-light filter portion and the first light conversion portion correspondingly overlap with the first blue light-emitting element, the green-light filter portion and the second light conversion portion correspondingly overlap with the second blue light-emitting element, and the blue-light filter portion and the light diffusion portion correspondingly overlap with the third blue light-emitting element.

20. The display device of claim 11, wherein the light-emitting unit at least comprises a first blue light-emitting element, a green light-emitting element and a second blue light-emitting element, the second substrate comprises a color filter layer and an optical layer, the color filter layer and the optical layer are provided at one side of the second substrate facing toward the light-emitting unit, the optical layer is disposed between the color filter layer and a light-emitting unit, the color filter layer comprises a red-light filter portion, a green-light filter portion and a blue-light filter portion, the optical layer comprises a light conversion portion, a first light diffusion portion and a second light diffusion portion, the red-light filter portion and the light conversion portion correspondingly overlap with the first blue light-emitting element, the green-light filter portion and the first light diffusion portion correspondingly overlap with the green light-emitting element, and the blue-light filter portion and the second light diffusion portion correspondingly overlap with the second blue light-emitting element.
